(19) United States
(12) Patent Application Publication
(10) Pub. No.: US 2010/0006961 A1
(43) Pub. Date: Jan. 14, 2010

(54) Recessed Germanium (Ge) Diode

(75) Inventors: John A. Yasaitis, Lexington, MA (US); Lawrence Jay Lowell, Derry, NH (US)

Correspondence Address: Sunstein Kann Murphy & Timbers LLP, 125 SUMMER STREET, BOSTON, MA, 02110-1618, US

(73) Assignee: ANALOG DEVICES, INC., Norwood, MA (US)

(21) Appl. No.: 12/169,825

(22) Filed: Jul. 9, 2008

(51) Int. Cl. H01L 31/00; H01L 21/00

(52) U.S. Cl. 257/431; 438/93; 257/E21.001; 257/E31.001

(57) ABSTRACT

A photodiode is formed in a recessed germanium (Ge) region in a silicon (Si) substrate. The Ge region may be fabricated by etching a hole through a passivation layer on the Si substrate and into the Si substrate and then growing Ge in the hole by a selective epitaxial process. The Ge appears to grow better selectively in the hole than on a Si or oxide surface. The Ge may grow up some or all of the passivation sidewall of the hole to conformally fill the hole and produce a recessed Ge region that is approximately flush with the surface of the substrate, without characteristic slanted sides of a mesa. The hole may be etched deep enough so the photodiode is thick enough to obtain good coupling efficiencies to vertical, free-space light entering the photodiode.

### TECHNICAL FIELD

The present invention relates to optoelectronic semiconductor fabrication and, more particularly, to fabrication of a recessed germanium (Ge) diode in a silicon substrate.

### BACKGROUND ART

Demand for low cost and high density near infrared (NIR) solid-state detectors has motivated development and use of germanium on silicon (Ge/Si) heterostructures to extend the optoelectronic application of Si technology. Ge/Si structures are currently being considered for NIR P/N detectors that can be integrated with Si complementary metal-oxide-semiconductor (CMOS) devices. Various research demonstrations of integrated Ge/Si diodes with CMOS have been made, including using sputtered polycrystalline germanium (poly-Ge) to form Ge/Si photodiodes after CMOS transistors were complete. Poly-Ge may be formed by various methods, including the use of plasma enhanced chemical vapor deposition (PECVD).

When integrating Ge on a Si substrate, such as for use as a free-space coupled, infrared (IR) photodiode detector, a substantial thickness (typically greater than 0.5 μm, and often 2 μm or more) of Ge is required. However, growing Ge on a Si surface creates large steps, which pose problems for subsequent fine geometric or lithographic planar semiconductor processing, such as placing leads on devices. Such processing typically requires step heights of less than about 1 μm.

### SUMMARY OF THE INVENTION

An embodiment of the present invention provides a method for fabricating a recessed semiconductor device in a substrate. The substrate may include a first material, such as silicon or silicon-on-insulator (SOI), and an optional passivation layer on the surface of the first material. A hole is etched through the passivation layer, if present, and at least about 0.5 μm into the first material. A second material, different than the first material, is epitaxially grown in the hole. The second material may include, for example, germanium or a germanium alloy. At least a portion of the grown second material may be doped.

The second material may be grown in stages. The second material may be epitaxially grown to partially fill the hole, then the grown second material may be heated to between about 750° C. and about 900° C. or to about 850° C. The heating may take place in situ in an epitaxial reactor used to epitaxially grow the second material. After heating the second material, additional second material may be epitaxially grown in the hole. The grown second material may be heated after the additional second material is grown. The growing and heating stages may be repeated.

Doping the at least a portion of the grown second material may form a photodiode. An optical path, perpendicular to the surface of the substrate, may be provided to the photodiode.

Optionally, a third material, that is different than the first material and different than the second material, may be epitaxially grown on a surface of the second material, and at least a portion of the grown third material may be doped. The third material may include a Group 3-5 compound, such as gallium arsenide.

Before etching the hole, a passivation layer may be formed on the surface of the substrate. The total thickness of passivation material on the surface of the substrate, through which the hole is etched, and the thickness of first material, through which the hole is etched, may be related by a ratio in the range of about 1:6 to about 1:1 or in a the range of about 1:4 to about 2:3. The total thickness of passivation material on the surface of the substrate, through which the hole is etched, may be at least about 0.3 μm, and the thickness of first material, through which the hole is etched, may be at least about 0.5 μm or about 1.2 μm.

The height of a ridge on the grown second material may be reduced, such as by heating the substrate, such as to a temperature between about 750° C. and about 900° C. Optionally or alternatively, the height of the ridge on the grown second material may be reduced by chemically-mechanically planarizing (CMP) at least a portion of the grown second material.

A polysilicon-based electrode may be deposited on at least a portion of the grown second material.

Another embodiment of the present invention provides a light conversion apparatus. A substrate includes a first material and a passivation layer on the surface of the first material. A second material is recessed into the passivation layer and into the first material. The second material extends to at least about 0.5 μm into the first material, as measured from the boundary between the passivation layer and the first material. At least a portion of the second material is doped to create a semiconductor device. The light conversion apparatus also includes at least one electrical connection to the semiconductor device.

The semiconductor device may include a photodiode. A structure may define an optical path, perpendicular to the surface of the substrate, to the photodiode.

A second passivation layer may overlay at least a portion of the passivation layer and define an opening through which an optical signal may pass to the semiconductor device. As noted, the semiconductor device may include a photodiode. The at least one electrical connection may include a polysilicon-based electrode overlaying the opening defined by the second passivation layer. The at least one electrical connection may be electrically coupled to the photodiode to extract photogenerated carriers from the photodiode.

Yet another embodiment of the present invention provides a method for for fabricating a semiconductor device on a substrate that includes a first material and a passivation layer on the surface of the first material. A hole is etched through the passivation layer to the first material. A second material, different than the first material, is epitaxially grown to partially fill the hole, and then the grown second material is heated, such as to a temperature between about 750° C. and about 900° C. The heading may occur in situ in an epitaxial reactor used to epitaxially grow the second material. After heating the grown second material, the second material is further epitaxially grown in the hole. At least a portion of the grown second material may be doped.

Optionally, after further epitaxially growing the second material in the hole, the grown second material is heated. Heating and growing the second material may be repeated in stages.

### BRIEF DESCRIPTION OF THE DRAWINGS

The invention will be more fully understood by referring to the following Detailed Description of Specific Embodiments in conjunction with the Drawings, of which:

FIG. 1 is a cross-sectional schematic diagram of a device that includes a waveguide-coupled arrangement, according to the prior art;

FIG. 2 is a top view, schematic diagram of a freespace-coupled photodiode, according to one embodiment of the present invention;

FIG. 3 is a cross-sectional view of the photodiode of FIG. 2;

FIG. 4 is a top view, schematic diagram of a flat-topped mesa structure, according to the prior art;

FIG. 5 is a cross-sectional view of the mesa structure of FIG. 4;

FIG. 6 is a cross-sectional view schematic diagram of another flat-topped mesa structure, according to the prior art;

FIG. 7 is a cross-sectional view, schematic diagram of a hypothetical flat-topped mesa structure grown in a recess;

FIG. 8 contains a set of cross-sectional view, schematic diagrams (a-c) illustrating progressive growth of Ge in a hole that was previously etched in a Si or SOI substrate, according to one embodiment of the present invention;

FIGS. 9, 10 and 11 are cross-sectional view, schematic diagrams illustrating a Si or SOI substrate at various stages of processing for growing a recessed Ge structure, according to one embodiment of the present invention;

FIG. 12 is a flowchart describing a fabrication process, according to embodiments of the present invention;

FIG. 13 contains a set of cross-sectional view, schematic diagrams (a-d) illustrating progressive growth of Ge in a hole that was previously etched in a Si or SOI substrate, according to another embodiment of the present invention;

FIG. 14 contains a set of cross-sectional view, schematic diagrams (a-d) illustrating progressive growth of Ge on a Si or SOI substrate, according to yet another embodiment of the present invention; and

FIG. 15 contains a set of cross-sectional view, schematic diagrams (a-d) illustrating progressive growth of Ge on a Si or SOI substrate, and growth of a third material on the Ge, according to an embodiment of the present invention.

### DETAILED DESCRIPTION OF SPECIFIC EMBODIMENTS

In accordance with the present invention, methods and apparatus are disclosed for providing a recessed germanium (Ge) region in a silicon (Si) substrate. The top of such a Ge region may be flush, or nearly flush, with the surrounding Si substrate or a passivation layer on the substrate, to facilitate subsequent semiconductor processing. However, the Ge region may be thick enough to obtain good coupling efficiencies to vertical, free-space light entering the Ge region. The Ge region may be fabricated by etching a hole through the passivation layer and into the Si substrate and then growing Ge in the hole by a selective epitaxial process.

### BACKGROUND

High-speed optical communication systems typically include optical fibers to carry optical signals and photodetectors coupled to the ends of the optical fibers to detect the optical signals and to convert the optical signals into electrical signals. Group 3-5 compound semiconductor photodiodes are commonly used as the photodetectors in such contexts. Group 3-5 compound semiconductors are fabricated on non-Si substrates, because group 3-5 compound semiconductors have material, thermal, doping, fabrication and other incompatibilities with Si. However, other devices, such as bipolar transistors that are commonly used with photodetectors, are well suited for fabrication on Si or silicon-on-insulator (SOD) substrates. Thus, the group 3-5 compound photodetectors cannot be fabricated on the same substrates as the devices to which they are commonly connected.

On the other hand, Ge is compatible with Si and SOI substrates and, as noted, germanium-on-silicon (Ge/Si) heterostructures, such as Ge photodiodes, have been found to be useful in optoelectronic application. For example, Ge has an appropriate band gap and absorption length for a wide range of wavelengths used in optical communication systems. Furthermore, it would be desirable to integrate Ge photodiodes with bipolar transistors and other related devices and circuits on a common substrate.

For good coupling efficiency between an incoming optical signal and a Ge region of a photodiode, the optical signal should be able to pass through a sufficient amount of Ge. “Responsivity” is a measure of electrical current output per unit of optical input power In general, responsivity varies with wavelength of the incident radiation. At wavelengths commonly used in communication systems, longer wavelengths typically require more Ge (“absorption length”) to generate acceptable electrical signals. For example, an optical signal having a wavelength of about 850 nm typical requires an absorption length of only about 0.2 μm. However, a 1,300 nm optical signal requires an absorption length of about 1 μm, and a 1,600 nm optical signal requires an even greater absorption length.

Many current integrated circuit (IC) processes involves fabricating advanced complementary metal-oxide-semiconductor devices on SOI substrates (CMOS on SOI). Such processes utilize very thin (often only about 0.25 μm or less thick) layers of Si. Ge structures having sufficient vertical (i.e., perpendicular to the surface of the substrate) absorption lengths cannot be fabricated in such thin layers of Si. Instead, to achieve sufficient absorption lengths, Ge is deposited in long, thin horizontal layers, and optical signals are coupled horizontally (i.e., parallel to the surface of the substrate) into the Ge. However, such coupling is difficult to achieve with high efficiency.

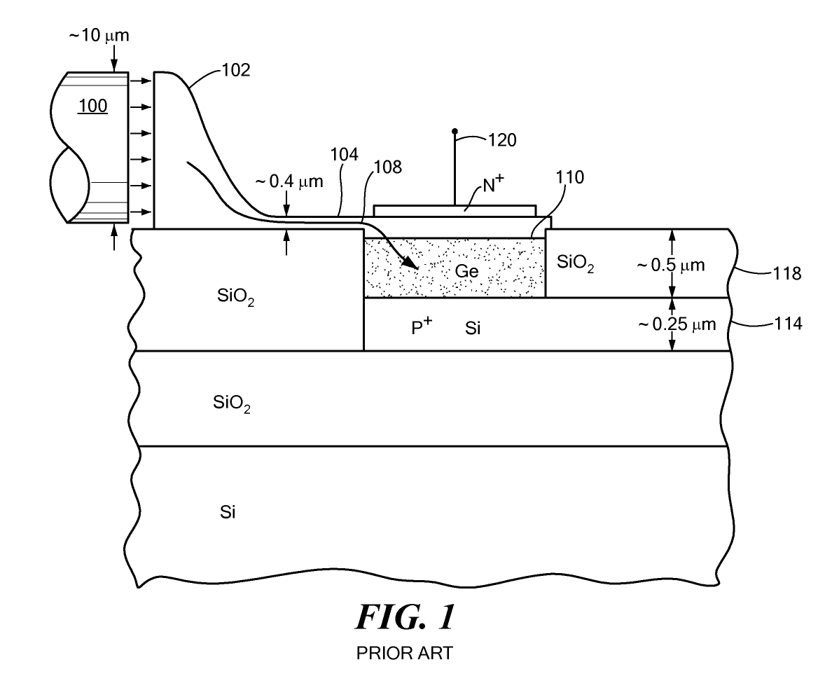

Optical fibers may be coupled to photodetectors using one of two methods: waveguide coupling and free-space coupling. FIG. 1 is a cross-sectional schematic diagram of a prior art device that includes a waveguide-coupled arrangement. An optical fiber 100 carries an optical signal, which exits the end of the optical fiber 100 and enters the large end 102 of a tapered mode coupler/waveguide 104. Once inside the mode coupler/waveguide 104, the optical signal 108 is carried across the surface of the device in the optical waveguide 104 and then the optical signal is coupled from the optical waveguide 104 to a photodetector, such as a Ge photodiode, in the device. Typically, the photodiode includes a very shallow Ge region 110 fabricated on a SOI substrate. The optical signal travels laterally through the Ge region 110, thus the absorption length is typically measured horizontally in waveguide-coupled devices.

A Si layer 114, on which the Ge region 110 is disposed, is typically only about 0.25 μm or less in thickness. To prevent coupling of the optical signal 108 to the Si layer 114, an insulating layer 118, typically more than about 1 μm in thickness, separates the mode coupler 104 from the Si layer 114. The optical signal 108 generates electron-hole pairs in the Ge region 110, and electrodes (one of which is shown at 120) connected to N+ and P+ junctions on opposite sides (top and bottom or left and right) of the Ge region 114 collect the generated carriers.

Mode couplers/waveguides are difficult and expensive to fabricate, at least in part due to their geometries and the need to fabricate very thick optical fiber-to-waveguide couplers, as shown in FIG. 1. These structures are also difficult to couple to photodiodes.

On the other hand, a vertical freespace-coupled device does not require a mode coupler/waveguide. However, the Ge region should be about 1.5 μm thick, depending on the wavelengths of interest, to provide a sufficient absorption length. Prior art methods of fabricating freespace-coupled devices involve growing Ge on a Si surface, which creates large steps that pose problems for subsequent semiconductor processing. Even waveguide-coupled devices include tall structures, such as the tall coupler portion 102 of the mode coupler/waveguide 104. Thus, both coupling methods involve tall structures, which pose problems for subsequent processing.

### Recessed Ge Photodiode

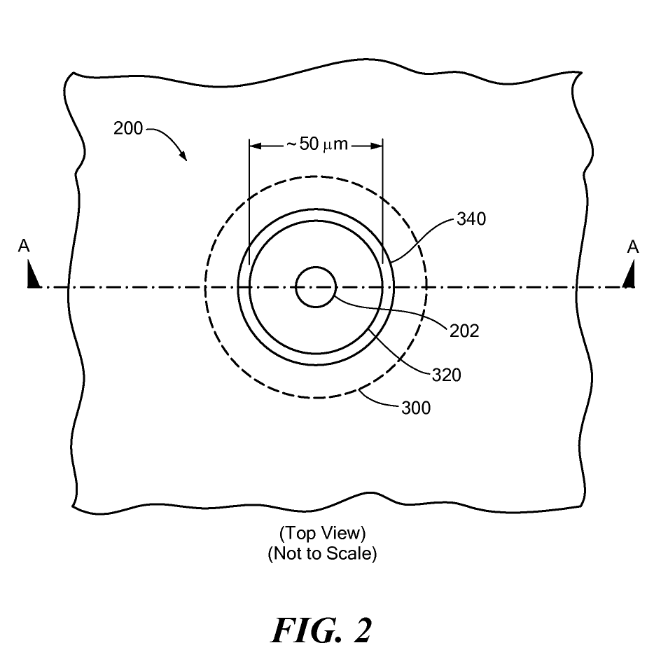

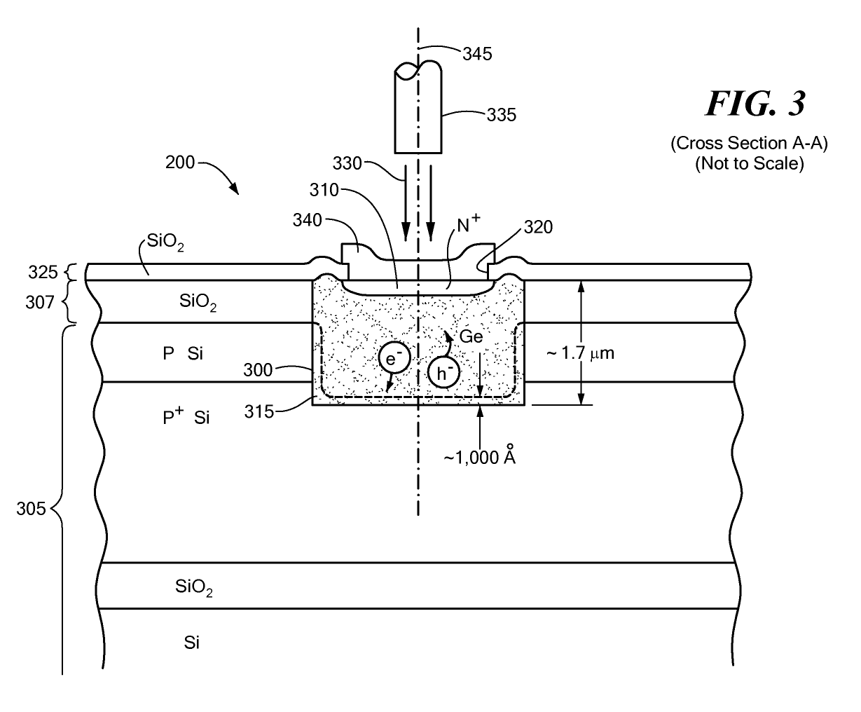

FIG. 2 is a top view, and FIG. 3 is a corresponding cross-sectional view, schematic diagram of a freespace-coupled photodiode 200, according to one embodiment of the present invention, which overcomes these problems. As best seen in FIG. 3, the photodiode 200 includes a thick Ge region 300 recessed in a SOI substrate 305 and an optional passivation layer 307. A portion 310 of the Ge region 300 is doped N+ to form a photodiode 200. Another portion 315 of the Ge region 300 may be heavily doped P+, such as by out-diffusion of boron from the P+ Si region. The P+ region 315 is typically very thin, about 1,000 Å. The photodiode 200 may be a p-type/intrinsic/n-type (PIN) photodiode. The portion 310 is doped during fabrication by etching an opening 320 in a silicon dioxide (SiO2) or other suitable passivation layer 325 and doping the region 310 through the opening 320, as discussed in more detail below. The size of the window 320 defines the extent of the N+ region 310.

An optical signal 330 from an optical fiber 335 or another source (such as a laser diode, etc.; not shown) may enter the Ge region 300 and generate electron-hole pairs. An electrode 340 that is sufficiently transparent at wavelengths of interest to transmit a sufficient portion of the optical signal 330 into the Ge region 300 may cover the opening 320 in the passivation layer 325 and provide one electrical connection to the photodiode 200 to collect the photogenerated carriers. A suitable polysilicon-based, transparent electrode is described in U.S. Pat. No. 7,205,525, titled “Light Conversion Apparatus with Topside Electrode,” by John Yasaitis, issued Apr. 17, 2007, the entire contents of which are incorporated herein by reference, for all purposes. Another electrical connection (not shown) to the photodiode 200 may be made conventionally. Optionally or alternatively, one or both electrical connections may be made by an optically-opaque metallic electrode, although such an electrode should be located so as not to completely occlude the optical signal 330, such as on one side (as viewed in FIG. 2) of the photodiode 200.

In FIG. 2, the illuminated portion of the photodiode 200 is indicated by a circle 202, and the Ge region 300, the opening 320 and the electrode 340 are shown to be round in shape. However, these shapes are design choices; thus, any or all of these features may be any shape. The optical signal beam 330 should be aligned with the center of the N+ region 310, as indicated by center line 345. The optical signal beam 330 should also be smaller (in plan view, as in FIG. 2) than the N+ region 310. Carriers generated beyond the N+ region 310 are in a lower field region than carriers generated in the N+ region 310, and these carriers are slow to collect and, thus, reduce the maximum frequency at which the diode 200 may operate. Because the opening 320 defines the size of the N+ region 310, the opening 320 should be larger than the optical signal beam 330. In one embodiment, the opening 320 is about 50 μm in diameter In one embodiment, the Ge region 300 (FIG. 3) is about 1.7 μm thick; however, other thicknesses may be used, such as according to the wavelengths of interest and desired coupling efficiencies.

To form the Ge region 300 (FIG. 3), a hole may be formed in the substrate, such as by etching the substrate, then Ge may be selectively epitaxially grown in the hole, until the top of the Ge region 300 is approximately level with the surface of the substrate, in a series of operations, as described below.

As used herein, “recessed” means disposed in a hole. The recessed material need not, however, fill the entire hole. For example, as shown in FIG. 3, the recessed Ge region 315 may be recessed in the substrate 305 and one passivation layer 307, but not in the second passivation layer 325.

### Surprising Results

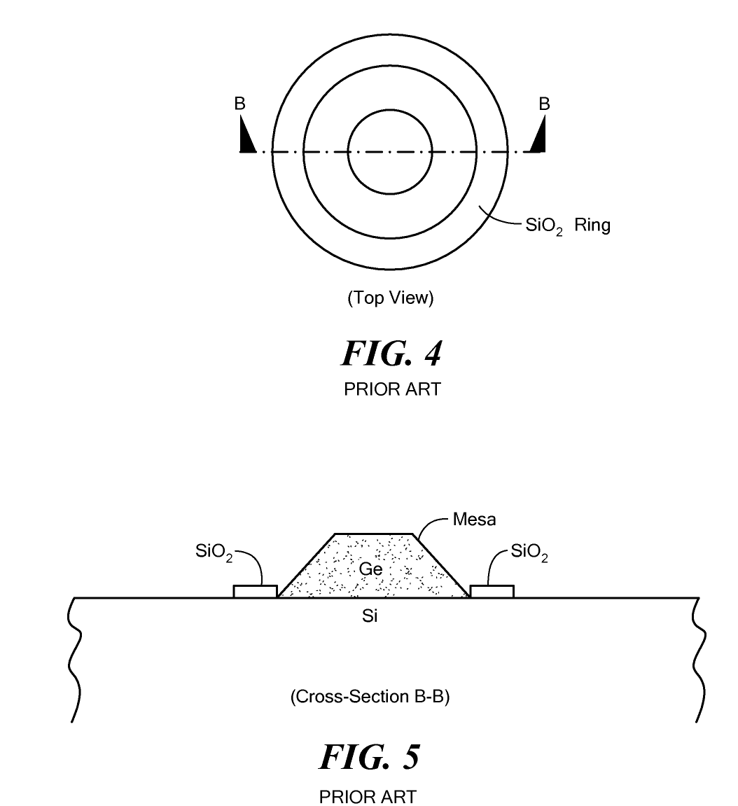

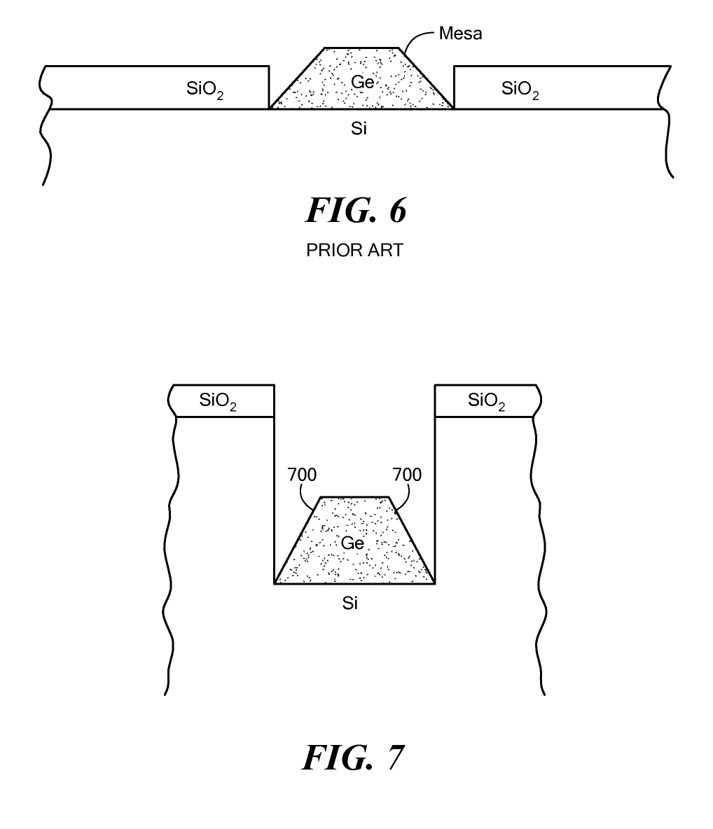

It is well known that selective epitaxial growth of Ge on a Si surface, such as within a ring of oxide, produces a flat-topped mesa structure with slanted sides, because some crystallographic planes grow faster than others. FIG. 4 is a top view, and FIG. 5 is a cross-sectional view, schematic diagram illustrating this effect Even using a thicker oxide boundary, as illustrated in FIG. 6, the Ge grows into a slant-sided mesa. Thus, it was thought that selectively growing Ge in a hole etched in a Si substrate would produce a mesa having slanted sides 700, as shown in FIG. 7.

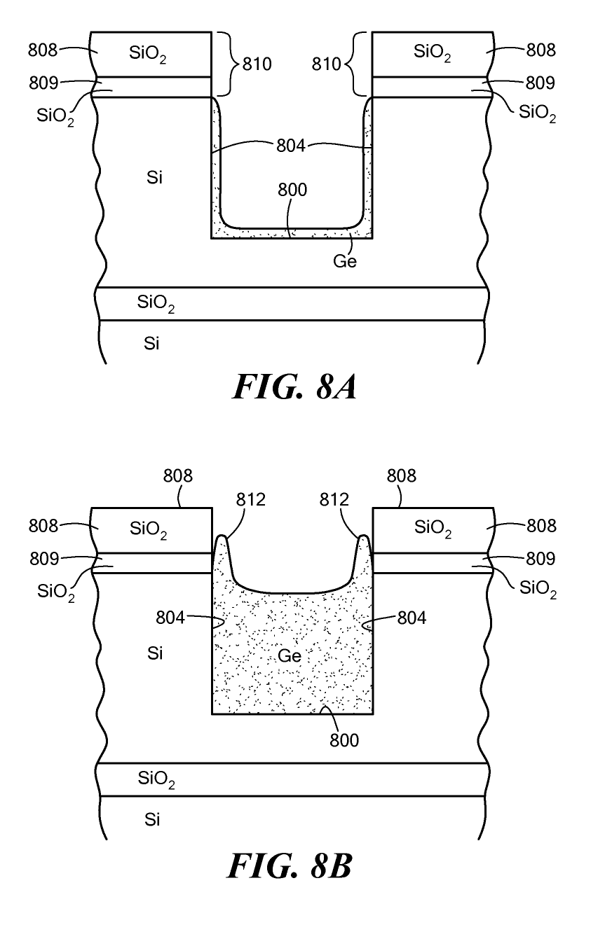

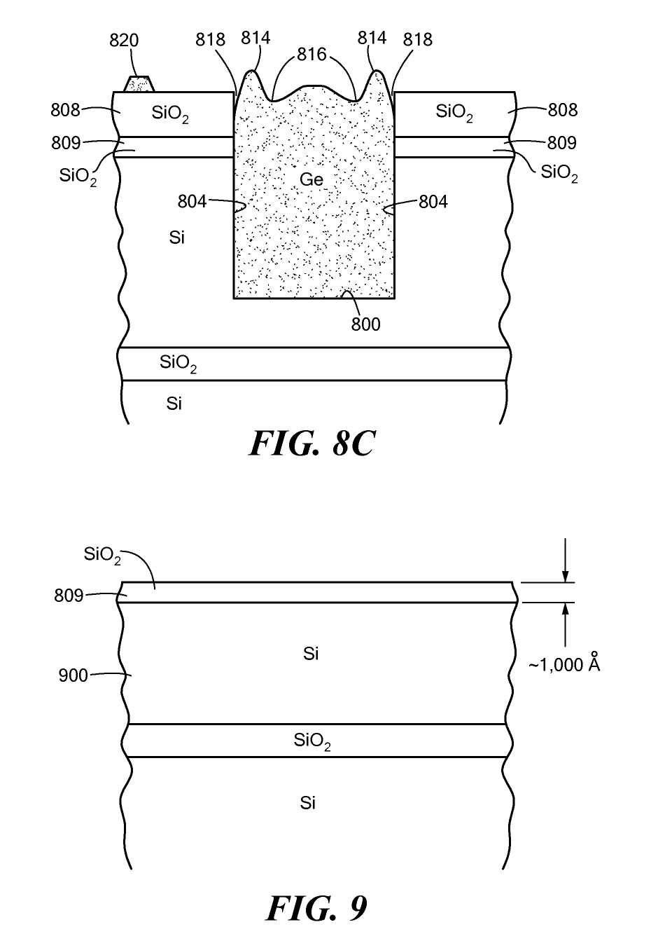

However, we have discovered that growing Ge selectively in a hole etched in Si and surrounded by oxide produces better results than selectively growing Ge on a Si surface surrounded by oxide. Surprisingly, the Ge may grow to conformally fill the hole and produce a recessed Ge region that is approximately flush with the surface of the substrate, without characteristic slanted sides 700 of a mesa (FIG. 7). FIG. 8 contains a set of schematic diagrams (a-c) illustrating progressive growth of Ge in a hole that was previously etched in a Si or SOI substrate having one or more layers of oxide, exemplified by layers 808 and 809. As can be seen in FIG. 8(a), the Ge grows on the bottom 800 of the hole and on the Si sidewalls 804 of the hole.

Ge selectively epitaxially grows on Si, but tends not to grow on oxide. Despite this tendency, if the surface of the Si substrate is covered with one or more layers of oxide 808 and 809, we have discovered that, surprisingly, there may be some Ge growth up or adjacent the oxide sidewall 810 in the hole. Ge that grows on the Si sidewall 804 (FIG. 8(a)) provides a crystallographic front, on which additional Ge grows, thereby causing growth of a ridge 812 (FIGS. 8(b-c)), rather than sloped sides as predicted and shown at 700 in FIG. 7.

### Fabrication Process

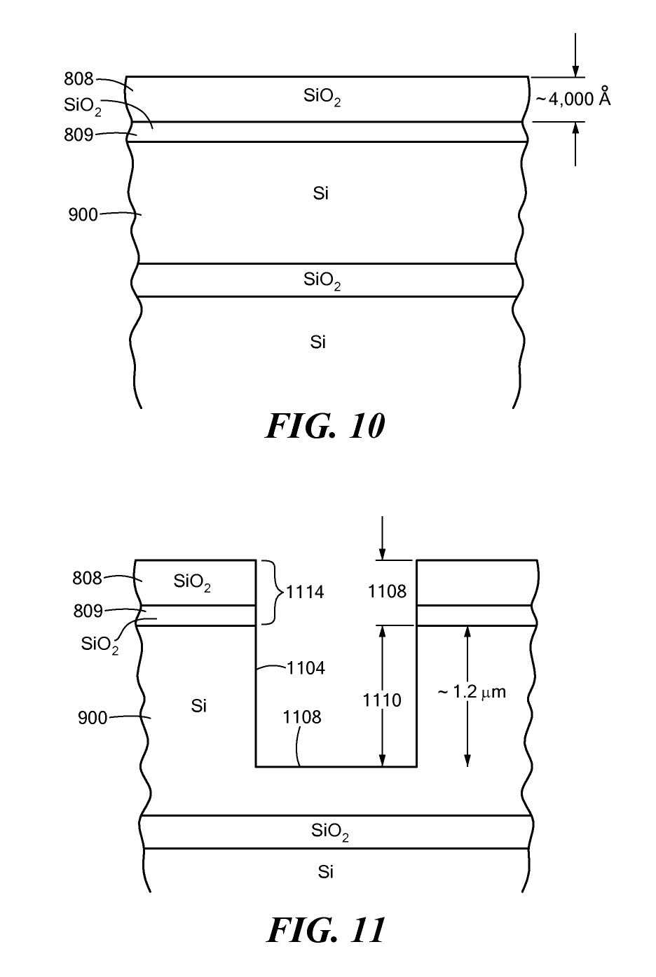

FIGS. 9, 10 and 11 are cross-sectional view, schematic diagrams illustrating a Si substrate at various stages of processing for growing a recessed Ge structure. Other fabrication processes, including forming bipolar transistors, may already have been performed on the substrate. Thus, as shown in FIG. 9, the surface of the Si substrate 900 may already have a relatively thin (about 1,000 Å) passivation layer 809, such as a layer of SiO2. As shown in FIG. 10, an additional apx. 4,000 Å layer of SiO2 808 is deposited, creating a layer of oxide that is about 0.5 μm thick. As shown in FIG. 11, the passivation layers 808 and 809 and the Si 900 are dry etched to a depth of about 1.2 μm of Si. Other depths may be used, such as based on an anticipated wavelength of optical signal and a desired absorption length.

The Si sidewalls 1104 and bottom 1108 of the etched hole should be prepared to provide native oxide-free silicon surfaces, on which to grow Ge. The surfaces may be conventionally prepared by a pre-bake at about 1,050° C. However, if bipolar transistors have already been formed on the substrate, the thermal budget for processing the substrate is limited. That is, there is a limit to which the temperature of the wafer should be raised. A conventional pre-bake could alter doping profiles of the bipolar transistors. The substrate temperature should, therefore, be kept below about 900° C.

To prepare the Si sidewalls 1104 and bottom 1108 without high temperature pre-baking, the Si sidewalls 1104 and bottom 1108 of the etched hole may be cleaned with hydrofluoric acid (HF), i.e., by applying a well-known HF last cleaning. HF last cleaning results in a Si surface that is free of silicon oxide and passivated with hydrogen.

Ge is then selectively grown on the sidewalls 1104 and bottom 1108 of the etched and cleaned hole, such as in a single-wafer epitaxial reactor. Stages of this growth are shown schematically in FIGS. 8(a-c). The above-referenced U.S. Pat. No. 7,205,525 describes a suitable procedure for epitaxially growing Ge on Si. This procedure includes epitaxially growing a seed Ge layer on the single-crystal Si base layer of the sidewalls 1104 and bottom 1108. This seed Ge layer approximately corresponds to the P+ region 315 shown in FIG. 3. The P+ region 315 may be heavily doped by out-diffusion of boron from the P+ Si region during growth of the seed Ge layer.

Returning to FIG. 11, we have found that, with an appropriate ratio of oxide thickness 1108 to Si sidewall height 1110, Ge conformally grows up the Si sidewalls 1104 of the hole, and may grow up some or all of the oxide sidewall 1114, as discussed above. In general, oxide thickness to Si sidewall height ratios of about 1:6 to about 1:1 produce satisfactory results. For example, a combination of about 0.5 μm oxide thickness 1108 and about 1.2 μm Si sidewall 1104 height produces satisfactory results.

Returning to FIG. 8(c), the grown Ge tends to have a small (apx. 0.6 μm) raised ridge 814 near the inside perimeter of the oxide sidewall 810 and a small trough 816 adjacent the ridge 814. The ridge 814 may be removed by any suitable process, such as chemical-mechanical planarization (CMP). Optionally or alternatively, the ridge 814 and trough 816 may be removed by flowing the Ge, such as during an annealing operation. The melting temperature of Ge (about 940° C.) is lower than the melting temperature of Si. Thus, heating the wafer to near or above the melting temperature of Ge causes the Ge to flow and level, without melting the Si. Such flowing may also fill in any gap 818 that may remains between the grown Ge and the oxide sidewall 810.

When Ge is grown on Si, a heteroepitaxial junction interface is created between the Si and the grown Ge. There is an about 4% difference between the crystal lattices of Si and Ge. Consequently, defects may form at the interface. The number of these defects may be reduced by annealing. Optionally, the annealing process may involve cycling between a high and a low (such as about 650° C.) temperature at about 30-second intervals, where the high temperature is sufficiently high to cause the Ge to flow.

We have found that annealing at about 850° C. causes the Ge to flow, which may largely level out the ridge 814 and fill in the trough 816. Cyclic annealing, using a high temperature of about 850° C. and a low temperature of about 650° C., also levels the Ge.

Although much or most of the surface of the substrate may be covered with a passivation layer 808, some Ge may nucleate and form Ge “islands” on the passivation layer 808 while the Ge is grown in the hole. An example of such an island is shown at 820 (FIG. 8(c)). To remove any such non-selective Ge depositions on the field oxide, a photoresist mask may be applied over the Ge that was grown in the hole, then a wet Ge etch (such as with HCl peroxide) may be performed. The resist mask may then be stripped.

As shown in FIG. 3, another passivation layer 325 may be deposited, and an opening 320 may be etched in the passivation layer 325. Polysilicon or another suitable transparent at wavelengths of interest (or non-transparent, as described above) electrode 340 may be deposited over the opening 320 and patterned to form an electrical connection to the photodiode. The Ge is implanted with dopant species, such as phosphorous, to create a doped region 310. This doping can occur before or after the topside electrode 340 is deposited.

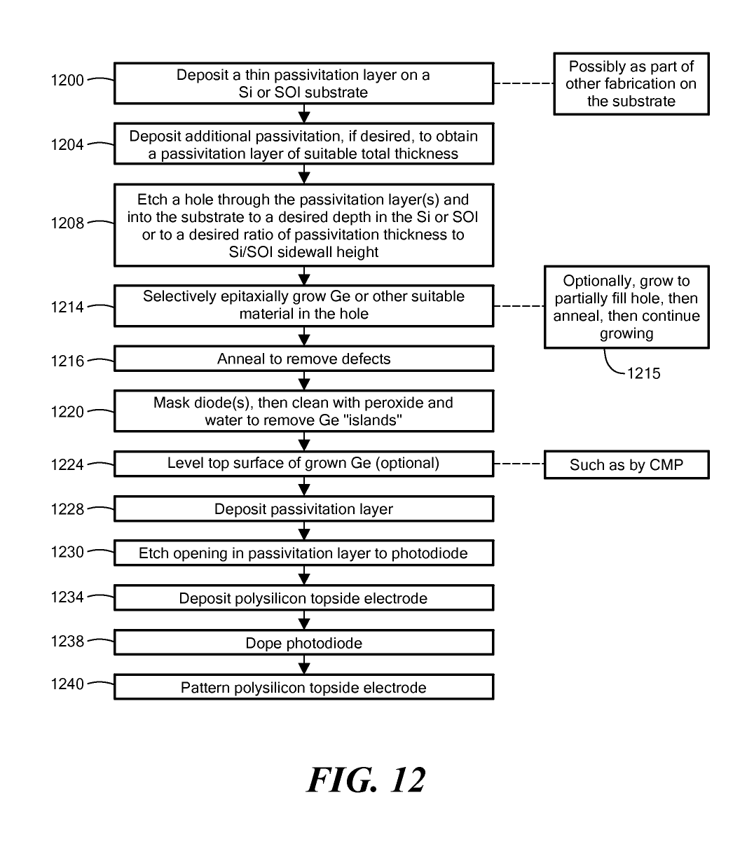

A fabrication process, according to one embodiment, is described in a flowchart in FIG. 12. At 1200, a thin passivation layer is deposited on a Si or SOI substrate. This may be the result of other fabrication that may already have been performed on the substrate. At 1202, additional passivation is deposited, if necessary, to obtain a passivation layer having a desired total thickness. At 1208, a hole is etched through the passivation layer(s) and into the Si of the substrate to a desired depth in the Si or to achieve a desired ratio of total passivation thickness to Si sidewall. Acceptable thicknesses and Si sidewall dimensions and ratios are described above.

At 1214, Ge is selectively epitaxially grown in the hole until the top of the grown Ge is approximately level with the top surface of the passivation layer or an expected top surface after the passivation layer is subsequently cleaned. The grown Ge may be annealed in situ within the epitaxial reactor as part of the operation 1214, or the Ge may be annealed in a separate operation 1216.

At 1220, the grown Ge region(s) may be masked to protect the regions during the subsequent cleaning operation, and then the field oxide may be cleaned with peroxide and water or another suitable cleaner to remove Ge islands that may have formed on the field oxide.

Optionally, the top surface of the grown Ge may be planarized by CMP at 1224. However, the surface of the grown Ge may be sufficiently level as a result of annealing at 1214 and/or 1216 to make planarization unnecessary.

Another passivation layer is deposited at 1228, and at 1230, an opening is etched in the passivation layer. At 1234, polysilicon is deposited to form a topside electrode. The photodiode is doped at 1238, and the polysilicon topside electrode is patterned at 1240.

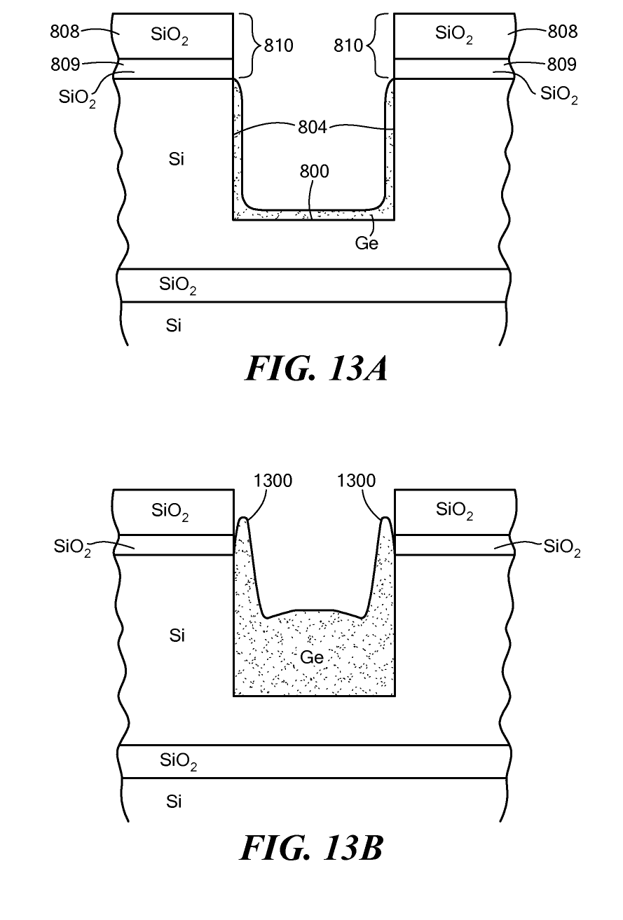

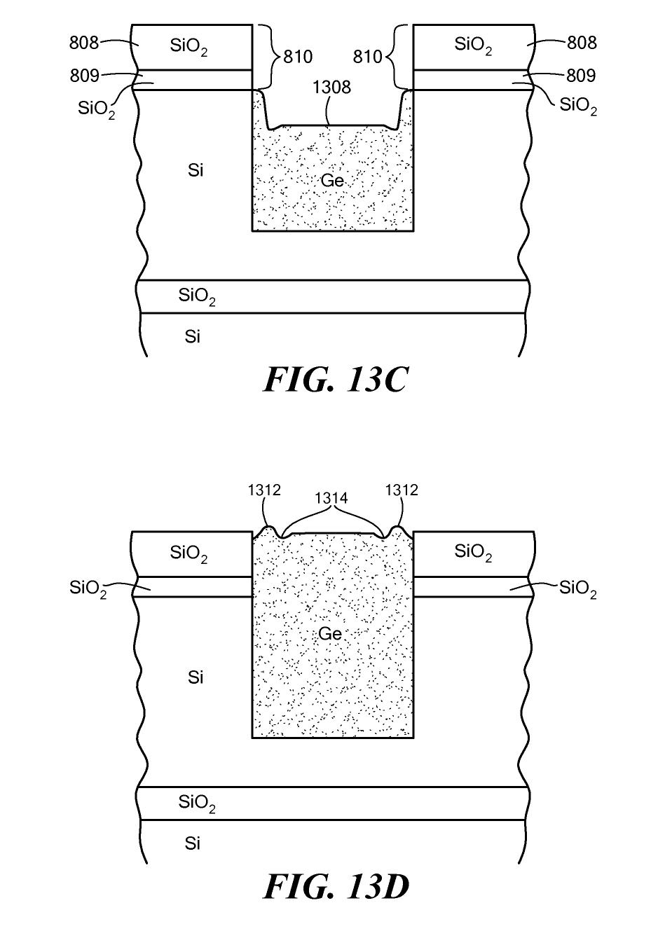

As noted with respect to FIG. 8(c), selectively epitaxially growing Ge in the hole often causes a ridge 814 and a trough 816 to form near the perimeter of the grown Ge. We have found that growing the Ge in stages (as indicated at 1215 in FIG. 12), rather than in a single stage, with an annealing stage after each growth stage, creates a Ge region having little or no ridge and little or no trough. FIG. 13(a-d) contains cross-sectional view, schematic diagrams illustrating a Si or SOI substrate at various stages of processing for growing a recessed Ge structure in stages.

After dry etching a hole and preparing the surface of the Si, Ge is selectively grown on the sidewalls and bottom of the etched and cleaned hole, as described above and as shown in FIG. 13(a). As the Ge grows, a small ridge 1300 forms, as shown in FIG. 13(b). After the Ge has been grown to partially fill the hole, the substrate is heated to anneal the Ge, as described above. As a result of being heated, the Ge flows and the surface 1308 of the Ge largely or completely levels, as shown in FIG. 13(c). Additional Ge may then be grown. Because the additional Ge grows on a level surface 1308, by the time the grown Ge fills the hole, as shown in FIG. 13(d), the additionally grown Ge exhibits little or no ridge 1312 and little or no trough 1314. The ridge 1312 and the trough 1314 may be leveled by further annealing and/or the ridge 1312 may be planarized, as described above.

The Ge may be grown at an intermediate temperature, such as about 600° C., and the annealing may be performed at a higher temperature, such as about 800° C. or 850° C. The annealing stages may be relatively short, such as about 30 seconds, so as to avoid dopant migration. The annealing may be performed in situ in the epitaxial reactor.

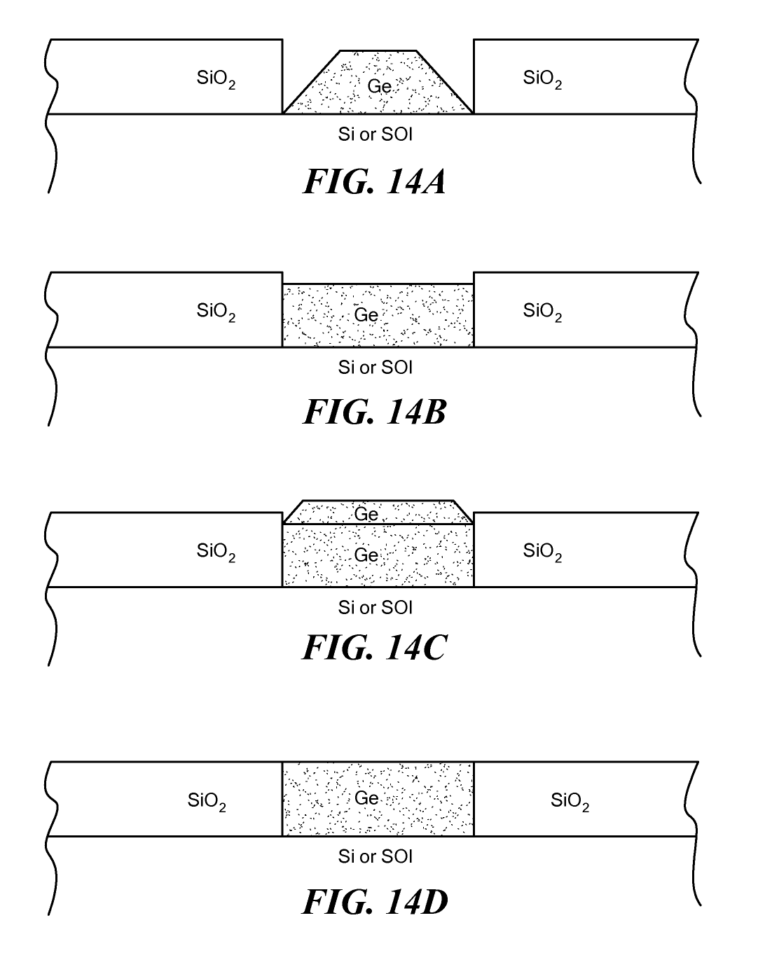

Although a two-stage Ge growth process is described, any number of growth stages, interspersed with annealing stages, may be used. Furthermore, a multi-stage growth process, as described, may be used to selectively grow Ge on the surface of a Si or SOI substrate, without etching a hole. FIG. 14(a-d) contains cross-sectional view, schematic diagrams illustrating a Si or SOI substrate at various stages of processing for growing a Ge structure in stages on the surface of the substrate. In FIG. 14(a), Ge is grown to partially fill a hole defined by SiO2. After the hole is partially filled, the substrate is annealed to cause the Ge to flow and level, as shown in FIG. 14(b). The Ge is then further grown, as shown in FIG. 14(c), and then further annealed to produce a level structure, as shown in FIG. 14(d).

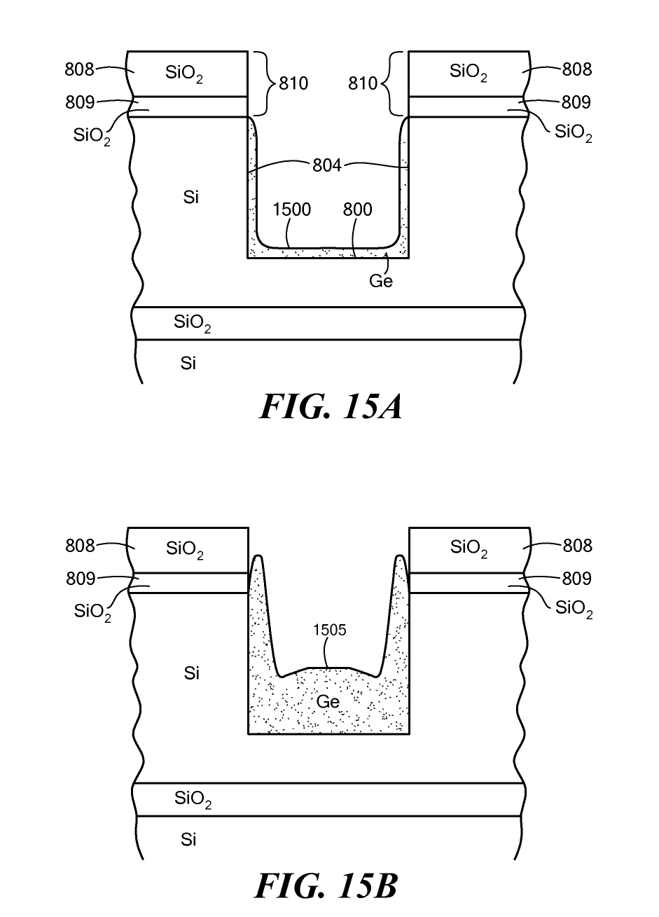

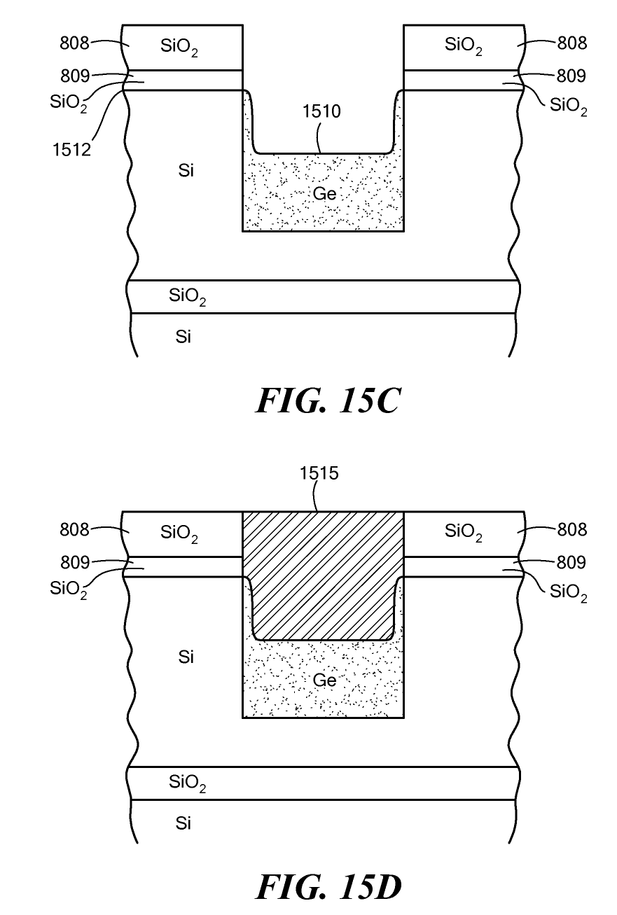

Although growing Ge in a recess in a substrate has been described, it is also possible to grow a layer of Ge in a recess, and then to grow a third material, different than Ge, on the Ge layer, thus producing a semiconductor device with a first and a second material in the recess, as schematically illustrated in FIG. 15(a-d). The third material may be a Group 3-5 compound, such as gallium arsenide (GaAs).

FIG. 15(a) shows a seed Ge layer 1500 epitaxially grown on a single-crystal Si base layer of the sidewalls 804 and bottom 800 of a recess, as described above with respect to FIGS. 8(a) and 13(a). Once the seed Ge layer 1500 is grown, additional Ge 1505 is grown, as shown in FIG. 15(b), until the Ge is at least about 0.5 μm thick. One or more of the above-described annealing processes may be used to level the surface 1510 of the Ge, as shown in FIG. 15(c). Although the surface 1510 is shown to be lower than the boundary 1512 between the SiO2 layer 809 and the Si, the Ge may be grown such that the surface 1510 is even with or above the boundary 1512, as needed.

All or part of the remainder of the recess may be filled by growing the third material 1515 on top of the Ge 1510. The third material 1515 may be doped. Other processing operations, such as planarization, annealing, flowing, etc., may be performed as described herein to level the surface of the second material 1515. Similarly, more than two materials may be successively grown in layers (not shown) in a single recess.

Using the disclosed method, a GaAs device, such as a light-emitting diode (LED), laser diode, transistor, etc., or other semiconductor device may be fabricated on a Si, SOI or other otherwise-incompatible substrate.

### Advantages of Recessed Ge Photodiodes

SiGe processes can yield very high speed (on the order of 40-50 GHz) bipolar devices and electrical circuits, such as transimpedance amplifiers (TIAs), which are often connected to photodiodes to amplify the optically generated charges into electrical signals for further processing, and circuits for driving high-speed optical sources, such as laser diodes. Such processes typically involve structures on relatively thick (such as about 2.5 μm) Si substrates. Thus, these processes are well suited for fabricating recessed Ge photodiodes, as described herein, yielding ICs that include both photodiodes and related devices and circuits.

In accordance with an exemplary embodiment, a recessed Ge photodiode and a method for fabricating such a photodiode is provided. While specific values chosen for these embodiments are recited, it is to be understood that, within the scope of the invention, the values of all of parameters may vary over wide ranges to suit different applications. For example, other thicknesses of passivation layers and depths of holes in Si substrates may be used. Furthermore, the disclosed method of fabricating a recessed Ge structure is applicable to other structures, such as waveguide-coupled photodetectors and Ge alloy structures grown in etched recesses.

While the invention is described through the above-described exemplary embodiments, it will be understood by those of ordinary skill in the art that modifications to, and variations of, the illustrated embodiments may be made without departing from the inventive concepts disclosed herein. For example, although some aspects of fabricating a recessed device have been described with reference to a flowchart, those skilled in the art should readily appreciate that functions, operations, decisions, etc. of all or a portion of each block, or a combination of blocks, of the flowchart may be combined, separated into separate operations or performed in other orders. In addition, although a Ge photodiode that is recessed in a Si substrate has been described, the disclosed methods and structures may be used with other materials and to fabricate other types of devices. Furthermore, disclosed aspects, or portions of these aspects, may be combined in ways not listed above. Accordingly, the invention should not be viewed as being limited to the disclosed embodiment(s).

What is claimed is:

1. A method for fabricating a recessed semiconductor device in a substrate, the substrate comprising a first material, the method comprising:
if a passivation layer is present on the surface of the first material, etching a hole through the passivation layer and at least about 0.5 μm into the first material, otherwise etching a hole at least about 0.5 μm into the first material;
epitaxially growing a second material, different than the first material, in the hole; and
doping at least a portion of the grown second material.

2. A method according to claim 1, wherein epitaxially growing the second material comprises:
(a) epitaxially growing the second material to partially fill the hole;
(b) after epitaxially growing the second material to partially fill the hole, heating the grown second material;
(c) after heating the grown second material, further epitaxially growing the second material in the hole.

3. A method according to claim 2, further comprising: (d) after further epitaxially growing the second material in the hole, heating the grown second material.

4. A method according to claim 3, further comprising repeating steps (c) and (d).

5. A method according to claim 2, wherein heating the grown second material comprises heating the grown second material to a temperature of about 850° C.

6. A method according to claim 2, wherein heating the grown second material comprises heating the grown second material to a temperature between about 750° C. and about 900° C.

7. A method according to claim 5, wherein heating the grown second material comprises heating the grown second material in situ in an epitaxial reactor used to epitaxially grow the second material.

8. A method according to claim 1, wherein the first material comprises silicon and the second material comprises germanium.

9. A method according to claim 8, wherein doping the at least a portion of the grown second material comprises forming a photodiode.

10. A method according to claim 9, further comprising providing an optical path, perpendicular to the surface of the substrate, to the photodiode.

11. A method according to claim 1, wherein the first material comprises silicon and the second material comprises a germanium alloy.

12. A method according to claim 1, wherein the first material comprises silicon-on-insulator.

13. A method according to claim 1, further comprising:
epitaxially growing a third material, different than the first material and different than the second material, in the hole, on a surface of the second material; and
doping at least a portion of the grown third material.

14. A method according to claim 13, wherein the third material comprises a Group 3-5 compound.

15. A method according to claim 13, wherein the third material comprises gallium arsenide.

16. A method according to claim 1, further comprising, before etching the hole, forming a passivation layer on the surface of the substrate.

17. A method according to claim 16, wherein the total thickness of passivation material on the surface of the substrate, through which the hole is etched, and the thickness of first material, through which the hole is etched, are related by a ratio in the range of about 1:6 to about 1:1.

18. A method according to claim 16, wherein the total thickness of passivation material on the surface of the substrate, through which the hole is etched, and the thickness of first material, through which the hole is etched, are related by a ratio in the range of about 1:4 to about 2:3.

19. A method according to claim 16, wherein the total thickness of passivation material on the surface of the substrate, through which the hole is etched, is at least about 0.3 μm; and the thickness of first material, through which the hole is etched, is at least about 0.5 μm.

20. A method according to claim 1, wherein the total thickness of passivation material on the surface of the substrate, through which the hole is etched, and the thickness of first material, through which the hole is etched, are related by a ratio in the range of about 1:6 to about 1:1.

21. A method according to claim 1, wherein the total thickness of passivation material on the surface of the substrate, through which the hole is etched, and the thickness of first material, through which the hole is etched, are related by a ratio in the range of about 1:4 to about 2:3.

22. A method according to claim 1, further comprising reducing the height of a ridge on the grown second material.

23. A method according to claim 22, wherein reducing the height of the ridge comprises heating the substrate.

24. A method according to claim 22, wherein reducing the height of the ridge comprises heating the substrate to a temperature between about 750° C. and about 900° C.

25. A method according to claim 22, wherein reducing the height of the ridge comprises chemical-mechanical planarizing at least a portion of the grown second material.

26. A method according to claim 1, further comprising depositing a polysilicon-based electrode on at least a portion of the grown second material.

27. A light conversion apparatus, comprising:
a substrate comprising a first material and a passivation layer on the surface of the first material;
a second material recessed into the passivation layer and the first material, the second material extending at least about 0.5 μm into the first material, as measured from the boundary between the passivation layer and the first material, at least a portion of the second material being doped to create a semiconductor device; and
at least one electrical connection to the semiconductor device.

28. A light conversion apparatus according to claim 27, wherein the semiconductor device comprises a photodiode.

29. A light conversion apparatus according to claim 28, further comprising a structure defining an optical path, perpendicular to the surface of the substrate, to the photodiode.

30. A light conversion apparatus according to claim 27, further comprising second passivation layer overlaying at least a portion of the passivation layer and defining an opening through which an optical signal can pass to the semiconductor device.

31. A light conversion apparatus according to claim 30, wherein the semiconductor device comprises a photodiode.

32. A light conversion apparatus according to claim 31, wherein the at least one electrical connection comprises a polysilicon-based electrode overlaying the opening defined by the second passivation layer and electrically coupled to the photodiode to extract photogenerated carriers from the photodiode.

33. A method for fabricating a semiconductor device on a substrate, the substrate comprising a first material and a passivation layer on the surface of the first material, the method comprising:
(a) etching a hole through the passivation layer to the first material;
(b) epitaxially growing a second material, different than the first material, to partially fill the hole;
(c) after epitaxially growing the second material to partially fill the hole, heating the grown second material;
(d) after heating the grown second material, further epitaxially growing the second material in the hole; and
doping at least a portion of the grown second material.

34. A method according to claim 33, further comprising: (e) after further epitaxially growing the second material in the hole, heating the grown second material.

35. A method according to claim 34, further comprising repeating steps (d) and (e).

36. A method according to claim 33, wherein heating the grown second material comprises heating the grown second material to a temperature between about 750° C. and about 900° C.

37. A method according to claim 36, wherein heating the grown second material comprises heating the grown second material in situ in an epitaxial reactor used to epitaxially grow the second material.
